(19) United States
(12) Patent Application Publication
(10) Pub. No.: US 2020/0133018 A1
(43) Pub. Date: Apr. 30, 2020

(54) DIFFRACTIVE OPTICAL ELEMENT MODULE

(71) Applicant: HIMAX TECHNOLOGIES LIMITED, Tainan City (TW)

(72) Inventors: Biing-Seng Wu, Tainan City (TW); Han-Yi Kuo, Tainan City (TW); Kuan-Ming Chen, Tainan City (TW); Chih-Yu Chuang, Tainan City (TW); Shi-Jen Wu, Tainan City (TW); Jui-Ni Li, Tainan City (TW); Cheng-Hung Tsai, Tainan City (TW); Chin-Yuan Chiang, Tainan City (TW); Chia-Ming Hsu, Tainan City (TW); Chiau-Ling Huang, Tainan City (TW)

(73) Assignee: HIMAX TECHNOLOGIES LIMITED, Tainan City (TW)

(21) Appl. No.: 16/548,852

(22) Filed: Aug. 23, 2019

Related U.S. Application Data
(60) Provisional application No. 62/749,675, filed on Oct. 24, 2018.

(51) Int. Cl. G02B 27/42; H01L 33/36; G02B 27/62; G02B 5/18

(52) U.S. Cl. CPC G02B 27/4272; G02B 5/188; G02B 27/62; H01L 33/36

(57) ABSTRACT

A DOE module including a transparent substrate, a first electrode, a second electrode, a first sensing wire, a sensing layer, a DOE layer, and an insulating layer is provided. The first electrode is disposed on the transparent substrate, and the second electrode is disposed on the transparent substrate. The first sensing wire is distributed on the transparent substrate and electrically connected to the first electrode. The sensing layer is distributed on the transparent substrate and electrically connected to the second electrode. The first sensing wire is insulated from the sensing layer to form a capacitance between the first sensing wire and the sensing layer. The DOE layer is disposed on the transparent substrate. The insulating layer covers the first sensing wire and the sensing layer. The insulating layer has a first opening and a second opening respectively exposing the first electrode and the second electrode.

### CROSS REFERENCE TO RELATED APPLICATION

This application claims the priority benefit of U.S. provisional application Ser. No. 62/749,675, filed on Oct. 24, 2018. The entirety of the above-mentioned patent application is hereby incorporated by reference herein and made a part of specification.

### BACKGROUND OF THE INVENTION

### 1. Field of the Invention

The invention generally relates to an optical module and, in particular, to a diffractive optical element (DOE) module.

### 2. Description of Related Art

Solid state lasers have been widely used in portable electronic devices to serve as a light source for detection, e.g. the light source of a face recognition device, an autofocusing camera, etc. The light source of a face recognition device emits a structured light, so as to form a light pattern on the face, which can be realized by adopting a DOE disposed on the path of the laser beam from a solid laser emitter to split the laser beam into multiple sub-beams.

When the light source works normally, there are no safety issues. However, if the DOE or glass of the light source is cracked, or if there is a water drop on or inside the light source, the path of the laser beam will be changed, which may cause safety issues. For example, the energy of the laser beam may concentrated on some positions and may damage the eyes of a user.

### SUMMARY OF THE INVENTION

Accordingly, the invention is directed to a diffractive optical element (DOE) module, which has a safety detection function.

According to an embodiment of the invention, a DOE module including a transparent substrate, a first electrode, a second electrode, a first sensing wire, a sensing layer, a DOE layer, and an insulating layer is provided. The first electrode is disposed on the transparent substrate, and the second electrode is disposed on the transparent substrate. The first sensing wire is distributed on the transparent substrate and electrically connected to the first electrode. The sensing layer is distributed on the transparent substrate and electrically connected to the second electrode. The first sensing wire is insulated from the sensing layer to form a capacitance between the first sensing wire and the sensing layer. The DOE layer is disposed on the transparent substrate. The insulating layer covers the first sensing wire and the sensing layer. The insulating layer has a first opening and a second opening respectively exposing the first electrode and the second electrode.

According to an embodiment of the invention, a DOE module including a transparent substrate, a first electrode, a second electrode, a first sensing wire, a sensing layer, and a DOE layer is provided. The first electrode is disposed on the transparent substrate, and the second electrode is disposed on the transparent substrate. The first sensing wire is distributed on the transparent substrate and electrically connected to the first electrode. The sensing layer is distributed on the transparent substrate and electrically connected to the second electrode. The first sensing wire is insulated from the sensing layer to form a capacitance between the first sensing wire and the sensing layer. The DOE layer covers the first sensing wire and the sensing layer. The DOE layer has a first opening and a second opening respectively exposing the first electrode and the second electrode.

Since the DOE module according to the embodiments of the invention has the first sensing wire and the sensing layer insulated from each other, when the DOE module is damaged or a water drop is on or inside the DOE module, the capacitance between the first sensing wire and the sensing layer is changed, which may be detected and a user may stop using the DOE module. Therefore, the safety of the user is ensured. Moreover, in the DOE module according to the embodiments of the invention, since the insulating layer or the DOE layer covering the first sensing wire and the sensing layer has openings to expose the first electrode and the second electrode, the capacitance between the first sensing wire and the sensing layer is easy to be detected. Therefore, the DOE module is easy to realize a safety detection function.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1A is a schematic cross-sectional view of a diffractive optical element (DOE) module according to an embodiment of the invention.

FIG. 1B is a schematic exploded view of the DOE module in FIG. 1A.

FIG. 1C is a detailed top view of the first electrode, the second electrode, the first sensing wire, and the sensing layer in FIG. 1B.

FIG. 2A is a schematic cross-sectional view of a DOE module according to an embodiment of the invention.

FIG. 2B is a schematic exploded view of the DOE module in FIG. 2A.

FIG. 3A and FIG. 3B show two other patterns of the first sensing wire and the second sensing wire in addition to the pattern of the first sensing wire and the second sensing wire shown in FIG. 1C.

FIG. 3C, FIG. 3D, and FIG. 3E show three other wiring patterns each including a grounded wire, a first sensing wire, and a second sensing wire.

FIG. 4A is a cross-sectional view of a transparent substrate, a first sensing wire, and a sensing layer according to another embodiment of the invention.

FIG. 4B is a cross-sectional view of a transparent substrate, a first sensing wire, a sensing layer, and an isolating layer according to yet another embodiment of the invention.

FIG. 5A shows another wiring patter including a first sensing wire and a sensing layer.

FIG. 5B shows another wiring pattern including a grounded wire, a first sensing wire, and a sensing layer.

FIG. 6A and FIG. 6B show two variations of the DOE layer in FIG. 2A and FIG. 2B.

FIG. 7A is a cross-sectional view of the transparent substrate, the first and second electrodes, the first and second sensing wires, the DOE layer, a spacer, conductive elements, and an electronic or optical component according to another embodiment.

FIG. 7B and FIG. 7C are respectively an exploded view and a perspective view of the structure of FIG. 7A.

FIG. 8A is a schematic cross-sectional view of a DOE module including the structure of FIG. 7A.

FIG. 8B is a schematic perspective view of the DOE module in FIG. 8A.

FIG. 9 is a schematic perspective view of a holder according to another embodiment.

FIG. 10A shows a wiring pattern of the first sensing wire and the second sensing wire according to another embodiment of the invention.

FIG. 10B shows a wiring pattern of the first sensing wire and the second sensing wire and an arrangement of the first and second electrodes according to another embodiment of the invention.

### DESCRIPTION OF THE EMBODIMENTS

Reference will now be made in detail to the present embodiments of the invention, examples of which are illustrated in the accompanying drawings. Wherever possible, the same reference numbers are used in the drawings and the description to refer to the same or like parts.

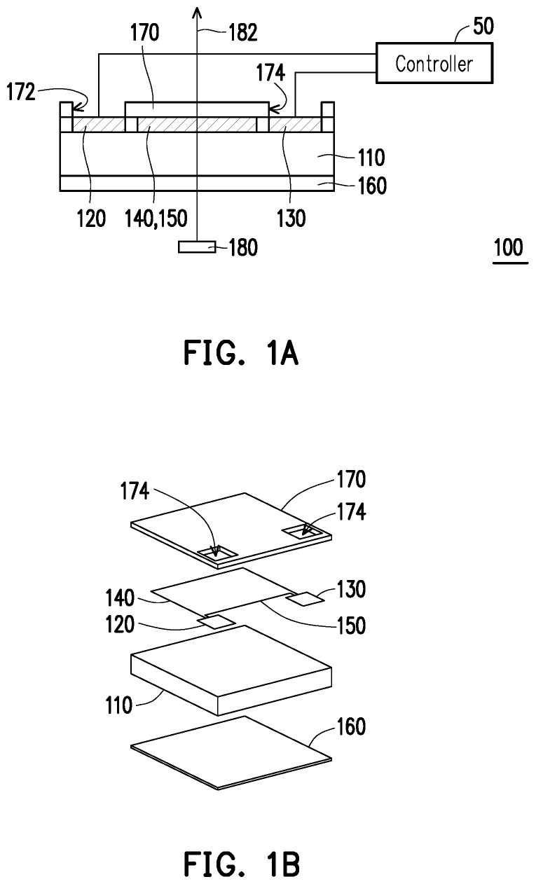

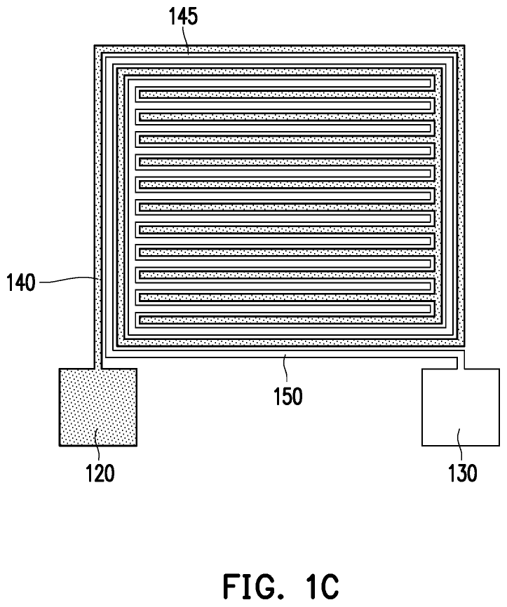

FIG. 1A is a schematic cross-sectional view of a diffractive optical element (DOE) module according to an embodiment of the invention. FIG. 1B is a schematic exploded view of the DOE module in FIG. 1A. FIG. 1C is a detailed top view of the first electrode, the second electrode, the first sensing wire, and the sensing layer in FIG. 1B. Referring to FIG. 1A to FIG. 1C, the DOE module 100 in this embodiment includes a transparent substrate 110, a first electrode 120, a second electrode 130, a first sensing wire 140, a sensing layer 150, a DOE layer 160, and an insulating layer 170. In this embodiment, the transparent substrate 110 is made of glass. However, in other embodiments, the transparent substrate 110 may be made of plastic or any other appropriate transparent material.

The first electrode 120 is disposed on the transparent substrate 110, and the second electrode 130 is disposed on the transparent substrate 110. The first sensing wire 140 is distributed on the transparent substrate 110 and electrically connected to the first electrode 120. The sensing layer 150 is distributed on the transparent substrate 110 and electrically connected to the second electrode 130. In this embodiment, the sensing layer 150 is a second sensing wire, and the first sensing wire 140 and the second sensing wire are alternately distributed on the transparent substrate 110, as shown in FIG. 1C. In this embodiment, the first electrode 120, the second electrode 130, the first sensing wire 140, and the sensing layer 150 are made of a transparent conductive material, for example, indium tin oxide (ITO), any other transparent conductive metal oxide, or any other appropriate transparent conductive material.

The first sensing wire 140 is insulated from the sensing layer 150 to form a capacitance between the first sensing wire 140 and the sensing layer 150. In this embodiment, the first sensing wire 140 is insulated from the sensing layer 150 by an insulating material 145. The insulating material 145 may be made of silicon dioxide, any other insulating oxide, or any other insulating nitride. The DOE layer 160 is disposed on the transparent substrate 110. The insulating layer 170 covers the first sensing wire 140 and the sensing layer 150. The insulating layer 170 has a first opening 172 and a second opening 174 respectively exposing the first electrode 120 and the second electrode 130. In this embodiment, the insulating layer 170 may be made of silicon dioxide, any other insulating oxide, any other insulating nitride, or any other insulating material.

In this embodiment, the DOE module 100 further includes a laser source 180 configured to emit a laser beam 182, and the transparent substrate 110, the DOE layer 160, the first sensing wire 140, the sensing layer 150, and the DOE layer 160 are disposed on a path of the laser beam 182. In this embodiment, the laser source 180 is, for example, a vertical-external-cavity surface-emitting-laser (VECSEL), an edge emitting laser, or any other appropriate laser diode. The DOE layer is a DOE that split the laser beam 182 into multiple sub-beams so as to form a structured light.

The first electrode 120 and the second electrode 130 are electrically connected to a controller 50 configured to detect self-capacitances, a mutual capacitance, or a combination thereof of the first electrode 120 and the second electrode 130. In this embodiment, the controller 50 may be designed through hardware description languages (HDL) or any other design methods for digital circuits familiar to people skilled in the art and may be a hardware circuit implemented through a field programmable gate array (FPGA), a complex programmable logic device (CPLD), or an application-specific integrated circuit (ASIC). Alternatively, the controller 230 may be a processor having computational capability.

When the DOE module is cracked or damaged, or there is a water drop on or inside the DOE module, the self-capacitances of the first electrode 120 and the second electrode 130 and the mutual capacitance between the first electrode 120 and the second electrode 130 are varied. The controller 50 may determine whether the DOE is in an abnormal condition according to the variation of at least one of the self-capacitances and the mutual capacitance. If the controller 50 determine that the DOE is in an abnormal condition, the controller 50 may stop the operation of the DOE module 100 or warn a user of the abnormality of the DOE module 100. Therefore, the user may be prevented from being harmed by the laser beam 182 in an abnormal condition.

Moreover, in the DOE module 100 according to this embodiment, since the insulating layer 170 covering the first sensing wire 140 and the sensing layer 150 has openings (e.g. the first opening 172 and the second opening 174) to expose the first electrode 120 and the second electrode 130, the capacitance between the first sensing wire 140 and the sensing layer 150 is easy to be detected. Therefore, the DOE module 100 is easy to realize a safety detection function.

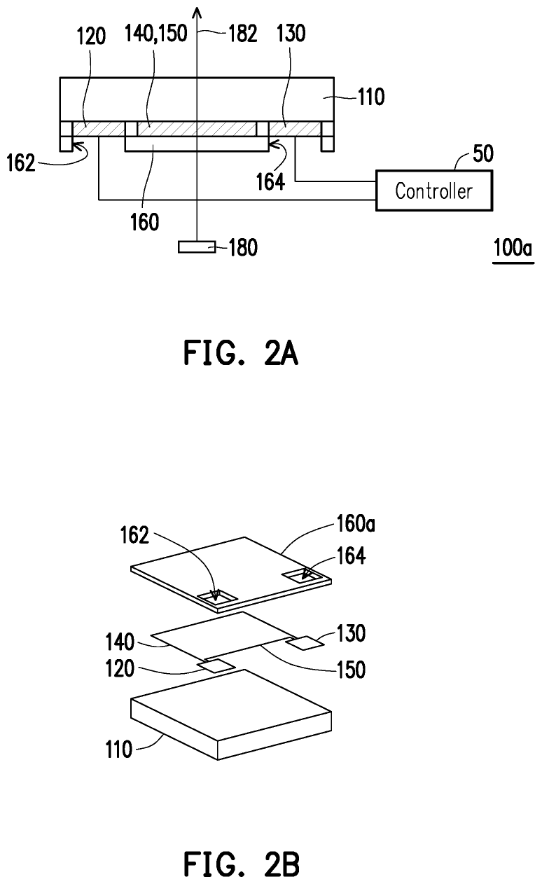

FIG. 2A is a schematic cross-sectional view of a DOE module according to an embodiment of the invention. FIG. 2B is a schematic exploded view of the DOE module in FIG. 2A. Referring to FIG. 2A and FIG. 2B, the DOE module 100a in this embodiment is similar to the DOE module 100 in FIG. 1A and FIG. 1B, and the main difference therebetween is as follows. In the DOE module 100a according to this embodiment, the DOE layer 160a covers the first sensing wire 140 and the sensing layer 150. The DOE layer 160a has a first opening 162 and a second opening 164 respectively exposing the first electrode 120 and the second electrode 130. In FIG. 1A and FIG. 1B, the DOE layer 160 and the first and second sensing wires (i.e. the first sensing wire 140 and the sensing layer 150) are respectively disposed on two opposite sides of the transparent substrate 110. However, in FIG. 2A and FIG. 2B, the DOE layer 160a and the first and second sensing wires are disposed on the same side of the transparent substrate 110. Moreover, in FIG. 1A, the laser beam 182 from the laser source 180 passes through the DOE layer 160, the transparent substrate 110, the first and second sensing wires, and the insulating layer 170 in sequence. However, in FIG. 2A, the laser beam 182 from the laser source 180 passes through the DOE layer 160a, the first and second sensing wires, and the transparent substrate 110 in sequence.

The DOE module 100a in this embodiment has advantages similar to those of the DOE module 100 in FIG. 1A and FIG. 1B, so that the advantages are not repeated herein.

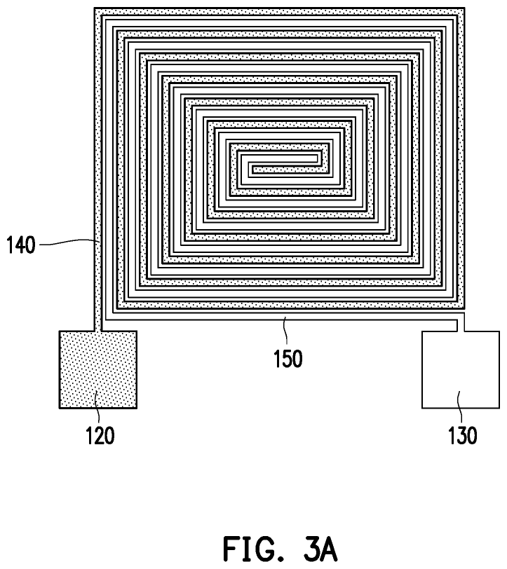

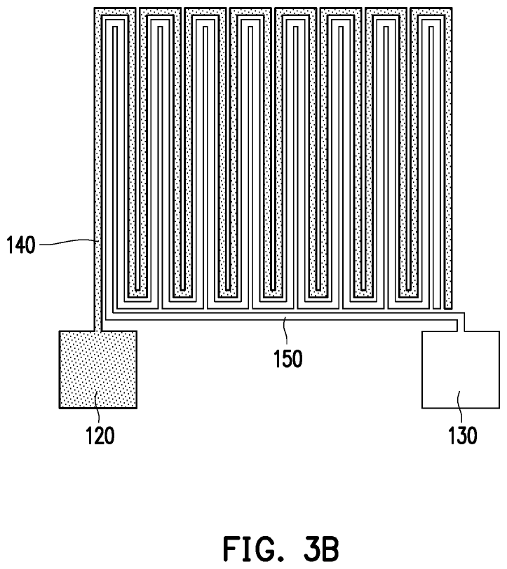

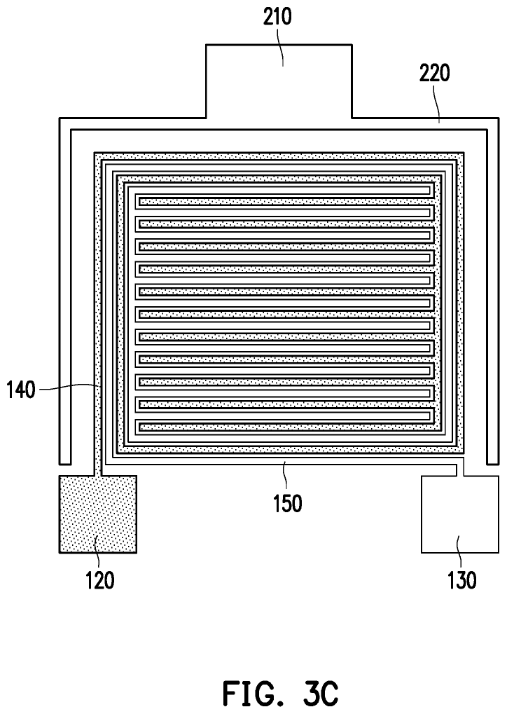

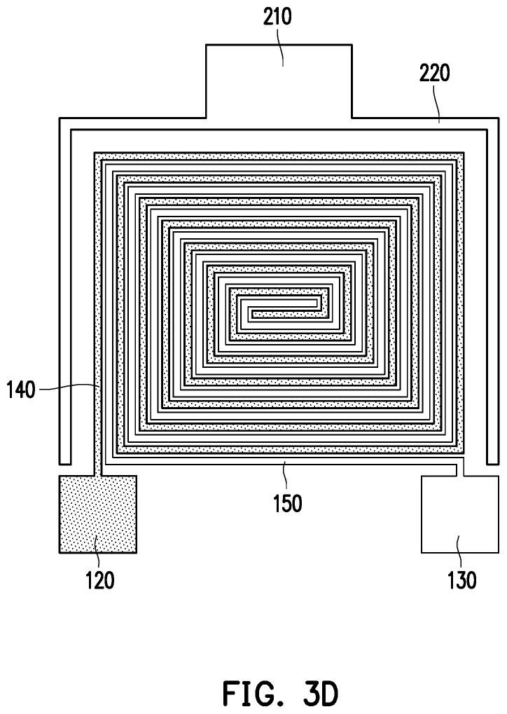

FIG. 3A and FIG. 3B show two other patterns of the first sensing wire 130 and the second sensing wire (i.e. the sensing layer 140) in addition to the pattern of the first sensing wire 130 and the second sensing wire (i.e. the sensing layer 140) shown in FIG. 1C. FIG. 3C, FIG. 3D, and FIG. 3E show three other wiring patterns each including a grounded wire 220, a first sensing wire 140, and a second sensing wire (i.e. the sensing layer 140). Referring to FIG. 3C, FIG. 3D, and FIG. 3E, the wiring patterns of FIG. 3C, FIG. 3D, and FIG. 3E are respectively similar to those of FIG. 1C, FIG. 3A, and FIG. 3B, and the main difference therebetween is as follows. In FIG. 3C, FIG. 3D, and FIG. 3E, the DOE module further includes a grounded wire 220 disposed on a periphery of the first sensing wire 140 and the sensing layer 150 to serve as a base of capacitance or be used for electrostatic discharge (ESD) shielding. The DOE module may further includes a grounded electrode 210, so that the grounded wire 220 may be easy to be grounded. In other embodiments, the grounded wire 220 may be replaced by a floated wire, and there is no grounded electrode 210.

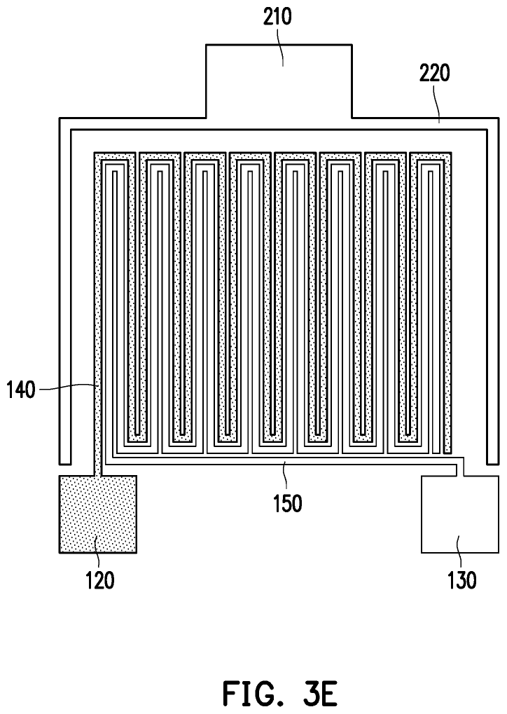

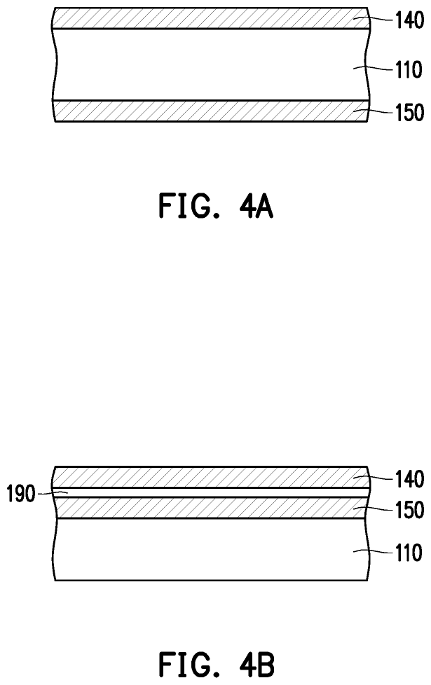

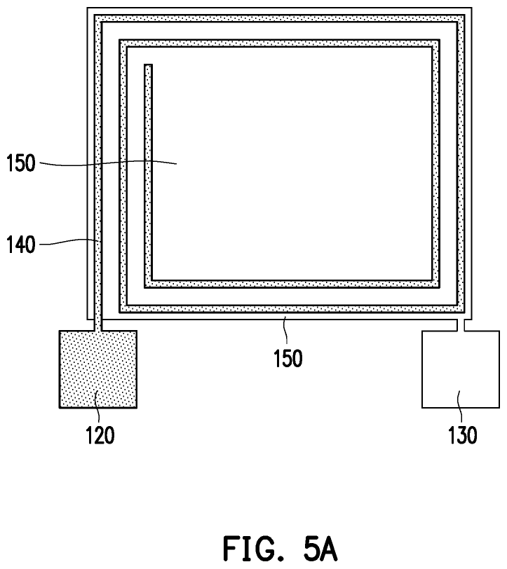

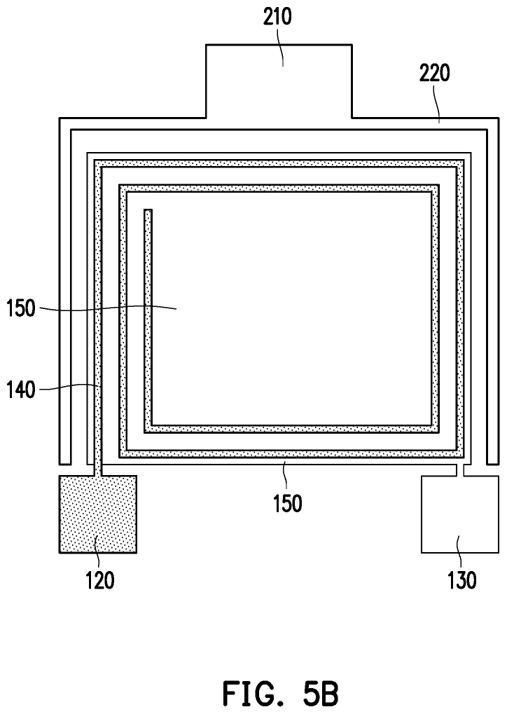

FIG. 4A is a cross-sectional view of a transparent substrate, a first sensing wire, and a sensing layer according to another embodiment of the invention. Referring to FIG. 4A, the arrangement of the transparent substrate 110, the first sensing wire 140, and the sensing layer 150 in FIG. 1A and FIG. 2A may be replaced by the arrangement of the transparent substrate 110, the first sensing wire 140, and the sensing layer 150 in FIG. 4A. In this embodiment, the first sensing wire 140 and the sensing layer 150 are disposed on two opposite sides of the transparent substrate 110. In this case, the patterns of the first sensing wire 140 and the sensing layer 150 may be as shown in FIG. 5A. Specifically, the sensing layer 150 may be shaped as a continuous sheet, and the first sensing wire 140 and the sensing layer 150 are in two different layers, respectively, which is different from FIG. 1A and FIG. 2A showing that the first sensing wire 140 and the sensing layer 150 (i.e. the second sensing wire) are in a single and same layer. In addition, the first sensing wire 140 and the sensing layer 150 (i.e. the second sensing wire) in FIG. 1C and FIG. 3A to FIG. 3E may be in two different layers, respectively, or in a single and same layer.

FIG. 4B is a cross-sectional view of a transparent substrate, a first sensing wire, a sensing layer, and an isolating layer according to yet another embodiment of the invention. Referring to FIG. 4B, the arrangement of the transparent substrate 110, the first sensing wire 140, and the sensing layer 150 in FIG. 1A and FIG. 2A may be replaced by the arrangement of the transparent substrate 110, the first sensing wire 140, and the sensing layer 150 in FIG. 4B. In this embodiment, the DOE module further includes an isolating layer 190 disposed between the first sensing wire 140 and the sensing layer 150 to insulate the first sensing wire 140 from the sensing layer 150, and the first sensing wire 140 and the sensing layer 150 are disposed on the same side of the transparent substrate 110. The isolating layer 190 may be made of an insulating material, e.g. silicon dioxide, any other insulating oxide, or any other insulating nitride. In this case, the patterns of the first sensing wire 140 and the sensing layer 150 may be as shown in FIG. 5A. Specifically, the sensing layer 150 may be shaped as a continuous sheet, and the first sensing wire 140 and the sensing layer 150 are in two different layers, respectively, which is different from FIG. 1A and FIG. 2A showing that the first sensing wire 140 and the sensing layer 150 (i.e. the second sensing wire) are in a single and same layer. In addition, the first sensing wire 140 and the sensing layer 150 (i.e. the second sensing wire) in FIG. 1C and FIG. 3A to FIG. 3E may be in two different layers, respectively, or in a single and same layer.

FIG. 5B shows another wiring pattern including a grounded wire 220, a first sensing wire 140, and a sensing layer 140. Referring to FIG. 5B, the wiring pattern of FIG. 5B is similar to that of FIG. 5A, and the main difference therebetween is as follows. In FIG. 5B, the DOE module further includes a grounded wire 220 disposed on a periphery of the first sensing wire 140 and the sensing layer 150 to serve as a base of capacitance or be used for electrostatic discharge (ESD) shielding. The DOE module may further includes a grounded electrode 210, so that the grounded wire 220 may be easy to be grounded. In other embodiments, the grounded wire 220 may be replaced by a floated wire, and there is no grounded electrode 210.

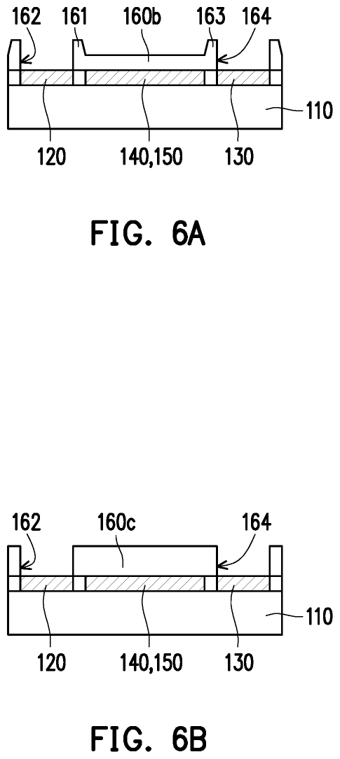

FIG. 6A and FIG. 6B show two variations of the DOE layer in FIG. 2A and FIG. 2B. Referring to FIG. 6A, the DOE layer 160b is similar to the DOE layer 160a and the difference therebetween is as follows. In FIG. 6A, the DOE layer 160b has protrusions 161 and 163 respectively adjacent to the first opening 162 and the second opening 164. The protrusions 161 and 163 are originally on the side walls of photoresists which are used to form the first opening 162 and the second opening 164. Referring to FIG. 6B, the DOE layer 160c is similar to the DOE layer 160b and the difference therebetween is as follows. The thickness of the DOE layer 160c is greater than the thickness of the DOE layer 160b, so that the DOE layer 160c has no protrusions 161 and 163.

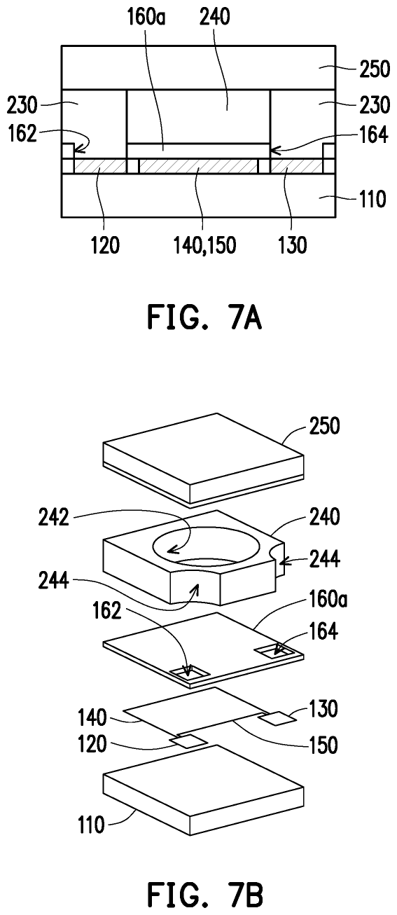

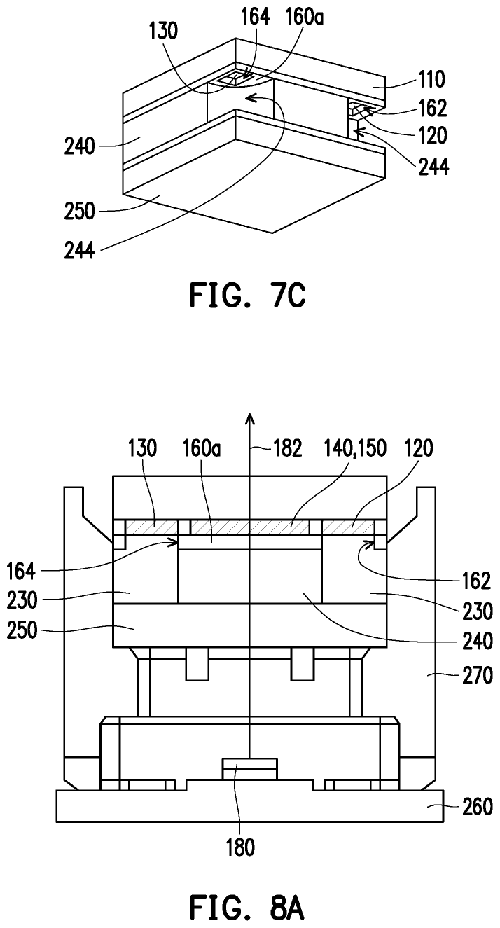

FIG. 7A is a cross-sectional view of the transparent substrate, the first and second electrodes, the first and second sensing wires, the DOE layer, a spacer, conductive elements, and an electronic or optical component according to another embodiment. FIG. 7B and FIG. 7C are respectively an exploded view and a perspective view of the structure of FIG. 7A. Referring to FIG. 7A to FIG. 7C, the structure of FIG. 7A is similar to the structure of the DOE module 100a in FIG. 2A, and the main difference therebetween is as follows. The DOE module in this embodiment further includes a spacer 240 and an electronic or optical component 250. The spacer 240 is disposed on the DOE layer 160a. The spacer 240 has an opening 242 to expose at least part of the first sensing wire 140 and a least part of the sensing layer 150. Moreover, the spacer 240 has two notches 244 to respectively expose the first electrode 120 and the second electrode 130. Besides, the electronic or optical component 250 is disposed on the spacer 240. The electronic or optical component 250 is, for example, a light sensor, a lens, a grating, or any other appropriate electronic or optical component. As a result, any other appropriate electronic or optical component may be integrated into the DOE module in this embodiment. In addition, the DOE module may include two conductive elements 230 respectively connected to the first electrode 120 and the second electrode 130 and respectively disposed in the two notches 244.

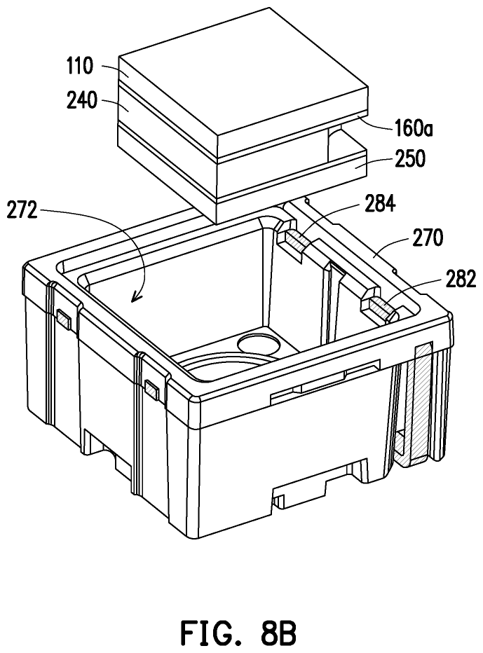

FIG. 8A is a schematic cross-sectional view of a DOE module including the structure of FIG. 7A, and FIG. 8B is a schematic perspective view of the DOE module in FIG. 8A. Referring to FIG. 8A and FIG. 8B, the DOE module 100d in this embodiment includes the structure shown in FIG. 7A, a circuit substrate 260, the laser source 180, and a holder 270. The light source 180 is disposed on the circuit substrate 260 and configured to emit a laser beam 182. The holder 270 is disposed on the circuit substrate 260 and surrounds the laser source 180. The structure of FIG. 7A is disposed on the holder 270. The laser beam 182 from the laser source 180 passes through the electronic or optical component 250, the opening 242 of the spacer 240, the DOE layer 160a, the first and second sensing wires, and the transparent substrate 110 in sequence. Besides, there may be conductors 282 and 284 on the holder 270 to contact with the conductive elements 230, so as to couple the first electrode 120 and the second electrode 130 with the controller 50 shown in FIG. 2A. The controller 50 may be disposed on the circuit substrate 260 or belong to an outside device.

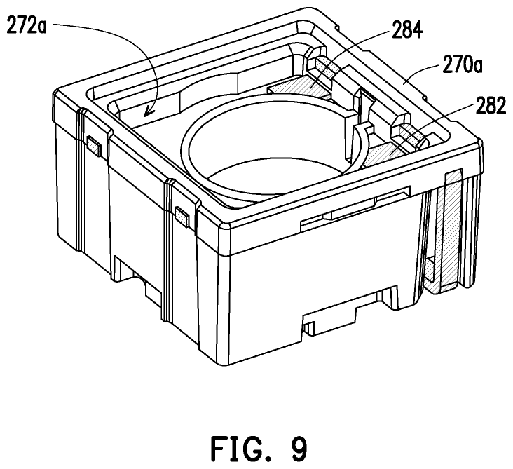

FIG. 9 is a schematic perspective view of a holder according to another embodiment. Referring to FIG. 9, the holder 270a in this embodiment is similar to the holder 270 in FIG. 8B, and the main difference is as follows. The holder 270 in FIG. 8B has a deep recess 272 to contain the thick structure of FIG. 7A. However, the holder 270a in FIG. 9 has a shallow recess 272a to contain thin structure of the DOE module, e.g. the DOE module 100 or 100a or the thin structure of FIG. 6A or FIG. 6B.

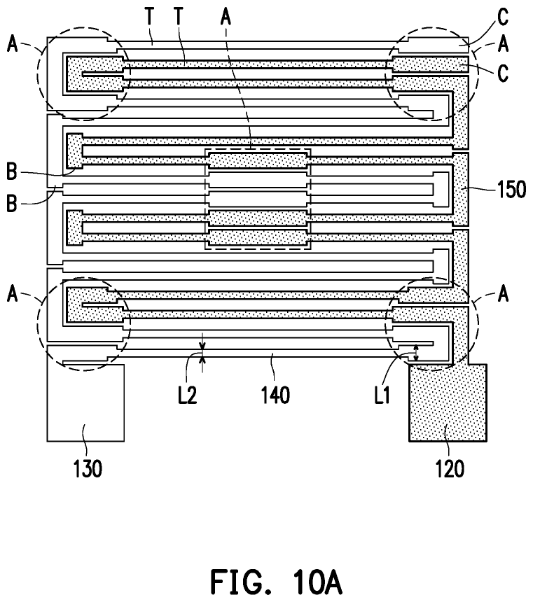

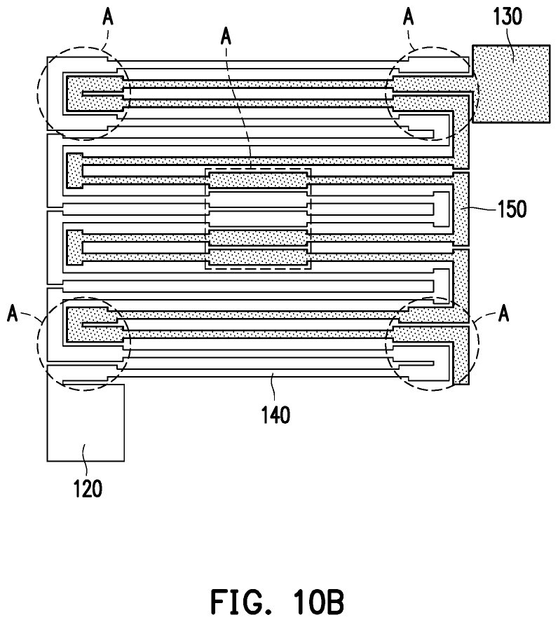

FIG. 10A shows a wiring pattern of the first sensing wire and the second sensing wire according to another embodiment of the invention. Referring to FIG. 10A, the wiring patter of the first sensing wire 140 and the second sensing wire (i.e. the sensing layer 150) may be replaced by the wiring pattern of the first sensing wire 140 and the second sensing wire (i.e. the sensing layer 150) in FIG. 10A. In this embodiment, the transparent substrate 110 as shown in FIG. 1B and FIG. 2B has at least one sensitive area A (five sensitive areas are shown in FIG. 10A). The linewidths L1 of the first sensing wire 140 and the second sensing wire (i.e. the sensing layer 150) within the sensitive areas A are greater than the linewidths L2 of the first sensing wire 140 and the second sensing wire outside the sensitive areas A. A greater linewidth L1 may increase the sensitivity in the sensitive area and increase the detected capacitance variation. Moreover, a smaller linewidth L2 may reduce the base capacitance so as to increase the sensitivity of the first sensing wire 140 and the second sensing wire.

In this embodiment, the sensitive areas A are located at the center and corners of the transparent substrate 110, but the positions and number of the sensitive areas A may be changed according to actual requirements in other embodiments. In this embodiment, if the water drop is at the center or the corners of the transparent substrate 110, this abnormal condition is easier to be detected.

In addition, a total length of branches B of the first sensing wire 140 is 0% to 20% of a length of a main trunk T of the first sensing wire 140, and a total length of branches B of the second sensing wire (i.e. the sensing layer 150) is 0% to 20% of a length of a main trunk T of the second sensing wire (i.e. the sensing layer 150). The aforementioned 0% means the first sensing wire 140 or the second sensing wire has no branch. As a result, the conductive path of each of the first sensing wire 140 and the second sensing wire is almost a single path without branches. Therefore, if the DOE module is cracked, the detected capacitance variation is obvious with respect to the base capacitance. Moreover, when the aforementioned numerical ranges are satisfied, the total length of the first sensing wire 140 and the second sensing wire is smaller, which provides a smaller base capacitance, so that the sensitivity of the first sensing wire 140 and the second sensing wire is increased.

FIG. 10B shows a wiring pattern of the first sensing wire and the second sensing wire and an arrangement of the first and second electrodes according to another embodiment of the invention. Referring to FIG. 10B, the structure of FIG. 10B is similar to the structure of FIG. 10A, and the main difference therebetween is as follows. In FIG. 10A, the first electrode 120 and the second electrode 130 are located adjacent to a same edge of the transparent substrate 110, and the tails C of the first sensing wire 140 and the second sensing wire are at a same corner of the transparent substrate 110 opposite to the first electrode 120 and the second electrode 130. Therefore, the sensitivity to the crack of the DOE module is decreased from one side of the transparent substrate 110 to another opposite side of the transparent substrate 110. To prevent this situation, in FIG. 10B, the first electrode 120 and the second electrode 130 are respectively disposed at two opposite corners of the transparent substrate 110, and the tail C of the first sensing wire 140 is adjacent to the second electrode. As a result, the sensitivity to the crack of the DOE module is more uniform among different areas of the transparent substrate 110. In other embodiments, the positions of the first electrode 120 and the second electrode 130 may be changed according to actual requirements, so as to change the sensitivity distribution of the DOE module. Therefore, a higher sensitivity may be provided to an area easier to be cracked.

Since the DOE module according to the embodiments of the invention has the first sensing wire and the sensing layer insulated from each other, when the DOE module is damaged or a water drop is on or inside the DOE module, the capacitance between the first sensing wire and the sensing layer is changed, which may be detected and a user may stop using the DOE module. Therefore, the safety of the user is ensured. Moreover, in the DOE module according to the embodiments of the invention, since the insulating layer or the DOE layer covering the first sensing wire and the sensing layer has openings to expose the first electrode and the second electrode, the capacitance between the first sensing wire and the sensing layer is easy to be detected. Therefore, the DOE module is easy to realize a safety detection function.

It will be apparent to those skilled in the art that various modifications and variations can be made to the structure of the invention without departing from the scope or spirit of the invention. In view of the foregoing, it is intended that the invention covers modifications and variations of this invention provided they fall within the scope of the following claims and their equivalents.

What is claimed is:

1. A diffractive optical element (DOE) module comprising:
a transparent substrate;
a first electrode disposed on the transparent substrate;
a second electrode disposed on the transparent substrate;
a first sensing wire distributed on the transparent substrate and electrically connected to the first electrode;
a sensing layer distributed on the transparent substrate and electrically connected to the second electrode, wherein the first sensing wire is insulated from the sensing layer to form a capacitance between the first sensing wire and the sensing layer;
a DOE layer disposed on the transparent substrate; and
an insulating layer covering the first sensing wire and the sensing layer, the insulating layer having a first opening and a second opening respectively exposing the first electrode and the second electrode.

2. The DOE module according to claim 1, wherein the sensing layer is a second sensing wire, and the first sensing wire and the second sensing wire are alternately distributed on the transparent substrate.

3. The DOE module according to claim 2, wherein the transparent substrate has a sensitive area, linewidths of the first sensing wire and the second sensing wire within the sensitive area are greater than linewidths of the first sensing wire and the second sensing wire outside the sensitive area.

4. The DOE module according to claim 2, wherein a total length of branches of the first sensing wire is 0% to 20% of a length of a main trunk of the first sensing wire, and a total length of branches of the second sensing wire is 0% to 20% of a length of a main trunk of the second sensing wire.

5. The DOE module according to claim 1, wherein the first sensing wire and the sensing layer are disposed on two opposite sides of the transparent substrate.

6. The DOE module according to claim 1 further comprising an isolating layer disposed between the first sensing wire and the sensing layer.

7. The DOE module according to claim 1 further comprising a grounded or floated wire disposed on a periphery of the first sensing wire and the sensing layer.

8. The DOE module according to claim 1, wherein the first electrode and the second electrode are electrically connected to a controller configured to detect self-capacitances, a mutual capacitance, or a combination thereof of the first electrode and the second electrode.

9. The DOE module according to claim 1 further comprising:
a circuit substrate;
a laser source disposed on the circuit substrate and configured to emit a laser beam; and
a holder disposed on the circuit substrate and surrounding the laser source, wherein the transparent substrate is disposed on the holder and on a path of the laser beam.

10. The DOE module according to claim 1, wherein the first electrode and the second electrode are located adjacent to a same edge of the transparent substrate.

11. The DOE module according to claim 1, wherein the first electrode and the second electrode are respectively disposed at two opposite corners of the transparent substrate.

12. A diffractive optical element (DOE) module comprising:
a transparent substrate;
a first electrode disposed on the transparent substrate;
a second electrode disposed on the transparent substrate;
a first sensing wire distributed on the transparent substrate and electrically connected to the first electrode;
a sensing layer distributed on the transparent substrate and electrically connected to the second electrode, wherein the first sensing wire is insulated from the sensing layer to form a capacitance between the first sensing wire and the sensing layer; and
a DOE layer covering the first sensing wire and the sensing layer, the DOE layer having a first opening and a second opening respectively exposing the first electrode and the second electrode.

13. The DOE module according to claim 12, wherein the sensing layer is a second sensing wire, and the first sensing wire and the second sensing wire are alternately distributed on the transparent substrate.

14. The DOE module according to claim 13, wherein the transparent substrate has a sensitive area, linewidths of the first sensing wire and the second sensing wire within the sensitive area are greater than linewidths of the first sensing wire and the second sensing wire outside the sensitive area.

15. The DOE module according to claim 13, wherein a total length of branches of the first sensing wire is 0% to 20% of a length of a main trunk of the first sensing wire, and a total length of branches of the second sensing wire is 0% to 20% of a length of a main trunk of the second sensing wire.

16. The DOE module according to claim 12, wherein the first sensing wire and the sensing layer are disposed on two opposite sides of the transparent substrate.

17. The DOE module according to claim 12 further comprising an isolating layer disposed between the first sensing wire and the sensing layer.

18. The DOE module according to claim 12 further comprising a grounded or floated wire disposed on a periphery of the first sensing wire and the sensing layer.

19. The DOE module according to claim 12, wherein the first electrode and the second electrode are electrically connected to a controller configured to detect self-capacitances, a mutual capacitance, or a combination thereof of the first electrode and the second electrode.

20. The DOE module according to claim 12 further comprising:
a circuit substrate;
a laser source disposed on the circuit substrate and configured to emit a laser beam; and
a holder disposed on the circuit substrate and surrounding the laser source, wherein the transparent substrate is disposed on the holder and on a path of the laser beam.

21. The DOE module according to claim 12 further comprising:
a spacer disposed on the DOE layer, the spacer having an opening to expose at least part of the first sensing wire and at least part of the sensing layer and two notches to respectively expose the first electrode and the second electrode; and
an electronic or optical component disposed on the spacer.

22. The DOE module according to claim 12, wherein the first electrode and the second electrode are located adjacent to a same edge of the transparent substrate.

23. The DOE module according to claim 12, wherein the first electrode and the second electrode are respectively disposed at two opposite corners of the transparent substrate.
